(19) United States
(12) Patent Application Publication
(10) Pub. No.: US 2023/0292562 A1
(43) Pub. Date: Sep. 14, 2023

(54) DISPLAY DEVICE

(71) Applicant: SAMSUNG DISPLAY CO., LTD., Yongin-si (KR)

(72) Inventor: Chun Gi YOU, Asan-si (KR)

(21) Appl. No.: 18/051,668

(22) Filed: Nov. 1, 2022

(30) Foreign Application Priority Data
Mar. 8, 2022 (KR) 10-2022-0029533

(51) Int. Cl. H10K 59/131

(52) U.S. Cl. CPC H01L 27/3276

(57) ABSTRACT

The present disclosure relates to a display device including a substrate, a transistor on the substrate, a first electrode connected to the transistor, a first passivation layer between the transistor and the first electrode, a wire on the first passivation layer, overlapping the first electrode, and defining an opening pattern, and a second passivation layer between the wire and the first electrode.

### CROSS-REFERENCE TO RELATED APPLICATION

This application claims priority to, and the benefit of, Korean Patent Application No. 10-2022-0029533 filed in the Korean Intellectual Property Office on Mar. 8, 2022, the entire contents of which are incorporated herein by reference.

### BACKGROUND

### 1. Field

The present disclosure relates to a display device.

### 2. Description of the Related Art

A display device displays images on a screen, and may include a liquid crystal display (LCD) or an organic light emitting diode (OLED) display. The display device is used for various electronic devices, such as a portable phone, a GPS, a digital camera, an electronic book, a portable game device, or various terminals.

The light emitting display device including an organic light emitting device has a self-luminance characteristic, and does not utilize a separate light source, unlike the LCD, so a thickness and a weight thereof may be reduced. Further, the light emitting display device has high-grade characteristics, such as low power consumption, high luminance, and a high response speed.

The organic light emitting device includes a plurality of pixels including an organic light emitting diode that is a self-light-emitting device, and a plurality of transistors and at least one capacitor for driving the organic light emitting diode are formed on respective pixels. Various wires for transmitting voltages (e.g., predetermined voltages) to respective pixels are formed.

An insulating layer may be positioned among the wires and the organic light emitting diodes. The insulating layer may include an organic material, and a gas may be generated in the insulating layer in a process for baking the organic material. The generated gas may be moved to an upper side of the insulating layer, and then may be discharged. However, a portion of the gas may be shielded by wires positioned on the insulating layer, and may not be discharged. The electrodes, the wires, or the light-emitting devices positioned on the insulating layer may be influenced by the gas not discharged to the outside and remaining on the insulating layer, and defects may be generated.

The above information disclosed in this Background section is only for enhancement of understanding of the background of the described technology, and therefore may contain information that does not form the prior art that is already known in this country to a person of ordinary skill in the art.

### SUMMARY

The described technology provides a display device for reducing or preventing the likelihood of electrodes, wires, or light-emitting devices positioned on an insulating layer being influenced by gas remaining in the insulating layer and generating defects.

One or more embodiments provide a display device including a substrate, a transistor on the substrate, a first electrode connected to the transistor, a first passivation layer between the transistor and the first electrode, a wire on the first passivation layer, overlapping the first electrode, and defining an opening pattern, and a second passivation layer between the wire and the first electrode.

The first passivation layer may include an organic insulating material.

The second passivation layer may include an organic insulating material.

The opening pattern of the wire may overlap the first electrode.

The opening pattern of the wire may have at least one of a circular shape, a polygonal shape, and a bar shape.

The wire may extend in a first direction, wherein the opening pattern of the wire has a bar shape extending in the first direction.

The wire may extend in a first direction, wherein the opening pattern of the wire has a bar shape extending in an oblique direction with respect to the first direction.

The wire may overlap a region between a center portion of the first electrode and an edge on one side of the first electrode.

The wire may be near an edge on one side of the first electrode.

The wire may overlap an edge on one side of the first electrode.

One side of the wire may correspond to an edge on one side of the first electrode.

The first electrode may define an opening pattern.

The first electrode may have a rectangular shape including two long sides extending in a first direction, and two short sides extend in a second direction that is perpendicular to the first direction, wherein the opening pattern of the first electrode has a rectangular shape including two short sides extending in the first direction, and two long sides extending in the second direction, and wherein the wire extends in the first direction.

The opening pattern of the first electrode may be at a center portion of the first electrode and an edge on one side of the first electrode.

The wire may overlap the opening pattern of the first electrode.

The opening pattern of the wire may overlap the first electrode and does not overlap the opening pattern of the first electrode.

The display device may further include a connection electrode for connecting the transistor to the first electrode, and at a same layer as the wire.

A voltage may be applied to the wire, which is connected to the transistor.

The wire may include a data line for applying a data signal, and a driving voltage line for applying a driving voltage, having a width that is greater than that of the data line, and having the opening pattern formed therein.

The wire may further include an initialization voltage line for applying an initialization voltage, and a common voltage line for applying a common voltage, wherein the opening pattern is formed in the initialization voltage line and the common voltage line.

According to the present disclosure, the likelihood of defects, such as in the electrodes of the display device, the wires, and the light-emitting devices may be reduced or prevented.

### BRIEF DESCRIPTION OF THE DRAWINGS

FIG. 1 shows a cross-sectional view of a display device according to one or more embodiments.

FIG. 2 shows a top plan view of some layers of a display device according to one or more embodiments.

FIG. 3 and FIG. 4 show top plan views of some layers of a display device according to one or more embodiments.

FIG. 5 to FIG. 8 show top plan views of some layers of a display device according to one or more embodiments.

FIG. 9 shows a cross-sectional view taken along the line IX-IX′ of FIG. 8.

FIG. 10 shows a top plan view of some layers of a display device according to one or more embodiments.

FIG. 11 shows a cross-sectional view taken along the line XI-XI′ of FIG. 10.

FIG. 12 shows a circuit diagram of a pixel of a display device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” may include A, B, or A and B. As used herein, “or” generally means “and/or,” and the term “and/or” includes any and all combinations of one or more of the associated listed items. For example, the expression, such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

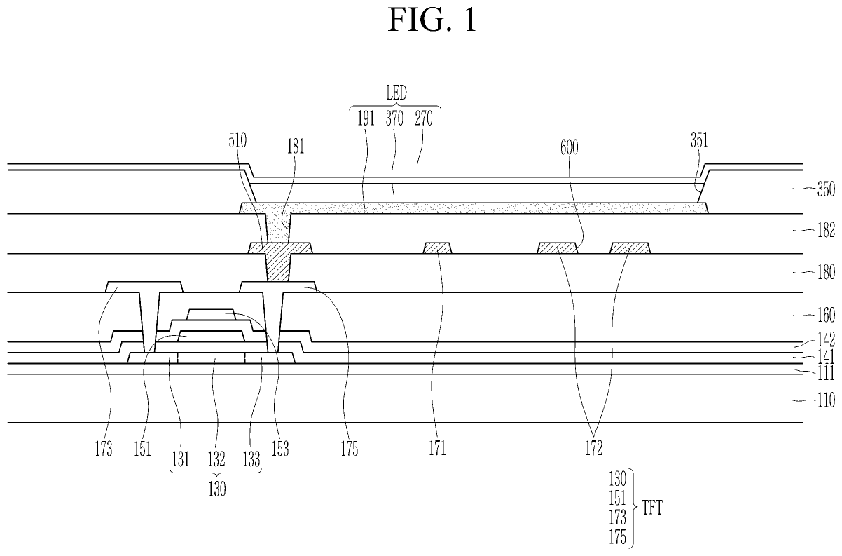

A display device according to one or more embodiments will now be described with reference to FIG. 1.

FIG. 1 shows a cross-sectional view of a display device according to one or more embodiments.

As shown in FIG. 1, the display device includes a substrate 110, a transistor TFT positioned on the substrate 110, and a light-emitting device LED connected to the transistor TFT.

The substrate 110 may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. The substrate 110 may include a flexible material that is bent or folded, and may be a single layer or a multilayer.

A buffer layer 111 may be positioned on the substrate 110. The buffer layer 111 may have a single-layered or multilayered structure. The buffer layer 111 may include an inorganic insulating material or an organic insulating material, such as a silicon nitride (SiNx), a silicon oxide (SiOx), or a silicon oxynitride (SiOxNy). The buffer layer 111 may be omitted in one or more embodiments. A barrier layer may be further positioned on the substrate 110 and the buffer layer 111. The barrier layer may have a single-layered or multilayered structure. The barrier layer may include an inorganic insulating material, such as a silicon nitride (SiNx), a silicon oxide (SiOx), or a silicon oxynitride (SiOxNy).

A semiconductor 130 may be positioned on the buffer layer 111. The semiconductor 130 may include a first region 131, a channel 132, and a second region 133. The first region 131 and the second region 133 may be positioned on respective sides of the channel 132 of the semiconductor 130. The semiconductor 130 may include a semiconductor material, such as amorphous silicon, polysilicon, or an oxide semiconductor.

A first gate insulating layer 141 may be positioned on the semiconductor 130. The first gate insulating layer 141 may have a single-layered or multilayered structure. The first gate insulating layer 141 may include an inorganic insulating material, such as a silicon nitride (SiNx), a silicon oxide (SiOx), or a silicon oxynitride (SiOxNy).

A first gate conductor including a gate electrode 151 may be positioned on the first gate insulating layer 141. The gate electrode 151 may overlap the channel 132 of the semiconductor 130. The gate electrode 151 may have a single-layered or multilayered structure. The gate electrode 151 may include a metal material, such as molybdenum (Mo), aluminum (Al), copper (Cu), and/or titanium (Ti). A doping process or a plasma-process may be performed when the gate electrode 151 is formed. A portion of the semiconductor 130 covered by the gate electrode 151 may not be doped or plasma-processed, and a portion of the semiconductor 130 that is not covered by the gate electrode 151 may be doped or plasma-processed, and may have a same characteristic as a conductor.

A second gate insulating layer 142 may be positioned on the gate electrode 151. The second gate insulating layer 142 may have a single-layered or multilayered structure. The second gate insulating layer 142 may have an inorganic insulating material, such as a silicon nitride (SiNx), a silicon oxide (SiOx), or a silicon oxynitride (SiOxNy).

A second gate conductor including a first storage electrode 153 is positioned on the second gate insulating layer 142. The first storage electrode 153 may have a single-layered or multilayered structure. The first storage electrode 153 may include a metal material, such as molybdenum (Mo), aluminum (Al), copper (Cu), and/or titanium (Ti). The first storage electrode 153 may overlap the gate electrode 151 to form a storage capacitor.

An interlayer insulating layer 160 may be positioned on the first storage electrode 153. The interlayer insulating layer 160 may have a single-layered or multilayered structure. The interlayer insulating layer 160 may have an inorganic insulating material or an organic insulating material.

A first data conductor including a source electrode 173 and a drain electrode 175 may be positioned on the interlayer insulating layer 160. The source electrode 173 and the drain electrode 175 may have a single-layered or multilayered structure. The source electrode 173 and the drain electrode 175 may have aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). For example, the source electrode 173 and the drain electrode 175 may include a lower layer, an intermediate layer, and an upper layer, the intermediate layer may be made of aluminum (Al), and the lower layer and the upper layer may be made of titanium (Ti).

The interlayer insulating layer 160 may include, or define, an opening overlapping the source electrode 173 and the first region 131 of the semiconductor 130. The source electrode 173 may be connected to the first region 131 of the semiconductor 130 through the opening of the interlayer insulating layer 160. The interlayer insulating layer 160 may include, or define, an opening overlapping the drain electrode 175 and the second region 133 of the semiconductor 130. The drain electrode 175 may be connected to the second region 133 of the semiconductor 130 through the opening of the interlayer insulating layer 160.

The semiconductor 130, the gate electrode 151, the source electrode 173, and the drain electrode 175 configure one transistor TFT. Depending on embodiments, the transistor TFT may not include the source electrode 173 and the drain electrode 175, but instead may include a source region and a drain region of the semiconductor 130. FIG. 1 shows one transistor TFT, and the display device according to one or more embodiments may include a plurality of pixels, and the pixels may respectively include a plurality of transistors.

A first passivation layer 180 may be positioned on the source electrode 173 and the drain electrode 175. The first passivation layer 180 may include an organic insulating material, such as a general-purpose polymer, such as poly(methyl methacrylate) (PMMA) or polystyrene (PS), a polymer derivative having a phenol-based group, an acryl-based polymer, an imide-based polymer, a polyimide, an acryl-based polymer, and a siloxane-based polymer.

A second data conductor including a connection electrode 510 may be positioned on the first passivation layer 180. The first passivation layer 180 may include, or define, an opening overlapping the connection electrode 510 and the drain electrode 175. The connection electrode 510 may be connected to the drain electrode 175 through the opening of the first passivation layer 180.

The second data conductor may further include a data line 171 and a driving voltage line 172. That is, the data line 171 and the driving voltage line 172 may be positioned on a same layer as the connection electrode 510. At least some of the transistors included in the respective pixels may be connected to the data line 171, and the others may be connected to the driving voltage line 172. The data line 171 transmits data signals, and luminance of light emitted by the light-emitting device LED is variable according to the data signals. The driving voltage line 172 transmits driving voltages, and the driving voltages may be constant. The data line 171 and the driving voltage line 172 may extend in directions that are parallel to each other in a plan view. The driving voltage line 172 may have a relatively greater width than the data line 171. The driving voltage line 172 may include, or define, an opening pattern 600.

In one or more embodiments, the second data conductor may further include an initialization voltage line and a common voltage line. The initialization voltage line may transmit an initialization voltage, and the common voltage line may transmit a common voltage. The initialization voltage and the common voltage may respectively be constant. The initialization voltage line and the common voltage line may extend in parallel to the driving voltage line 172 in a plan view. The initialization voltage line and the common voltage line may include, or define, an opening pattern.

A second passivation layer 182 may be positioned on the second data conductor including the connection electrode 510, the data line 171, and the driving voltage line 172. The second passivation layer 182 may include an organic insulating material, such as a general-purpose polymer, such as poly(methyl methacrylate) (PMMA) or polystyrene (PS), a polymer derivative having a phenol-based group, an acryl-based polymer, an imide-based polymer, a polyimide, an acryl-based polymer, and a siloxane-based polymer.

A first electrode 191 may be positioned on the second passivation layer 182. The first electrode 191 is also referred to as an anode, and may be configured with a single layer including a transparent conductive oxide layer or a metal material, or a multilayer including them. The transparent conductive oxide layer may include an indium tin oxide (ITO), a poly-ITO, an indium zinc oxide (IZO), an indium gallium zinc oxide (IGZO), and an indium tin zinc oxide (ITZO). The metal material may include silver (Ag), molybdenum (Mo), copper (Cu), gold (Au), and aluminum (Al). For example, the first electrode 191 includes a lower layer, an intermediate layer, and an upper layer. The lower layer of the first electrode 191 may be positioned on the second passivation layer 182, the intermediate layer may be positioned on the lower layer, and the upper layer may be positioned on the intermediate layer. The intermediate layer of the first electrode 191 may be made of a material that is different from that of the lower layer and the upper layer. For example, the intermediate layer may be made of silver (Ag), and the lower layer and the upper layer may be made of an ITO.

The second passivation layer 182 may include, or define, an opening 181 overlapping the connection electrode 510 and the first electrode 191. The first electrode 191 may be connected to the connection electrode 510 through the opening 181 of the second passivation layer 182. The connection electrode 510 may connect between the drain electrode 175 and the first electrode 191. However, without being limited thereto, the drain electrode 175 may be directly connected to the first electrode 191 without the connection electrode depending on embodiments.

A partition wall 350 may be positioned on the first electrode 191. A pixel opening 351 may be formed in the partition wall 350, and may overlap the first electrode 191. The pixel opening 351 may overlap a center portion of the first electrode 191. Hence, the partition wall 350 may be formed to cover the edge of the first electrode 191. The partition wall 350 may include an organic insulating material, such as a general-purpose polymer, such as poly(methyl methacrylate) (PMMA) or polystyrene (PS), a polymer derivative having a phenol-based group, an acryl-based polymer, an imide-based polymer, a polyimide, an acryl-based polymer, and a siloxane-based polymer.

An emission layer 370 may be positioned in the pixel opening 351 of the partition wall 350. The emission layer 370 may overlap the first electrode 191. The emission layer 370 may include organic materials for emitting red, green, and blue light. The emission layer 370 may include a high-molecular or low-molecular organic material. The emission layer 370 is shown to be a single layer, but in actuality, auxiliary layers, such as a hole injection layer (HIL), a hole transporting layer (HTL), an electron transporting layer (ETL), and an electron injection layer (EIL) may be further positioned above/below the emission layer 370. In this instance, the hole injection layer and the hole transport layer may be positioned below the emission layer 370, and the electron transport layer and the electron injection layer may be positioned above the emission layer 370.

A second electrode 270 may be positioned on the emission layer 370 and the partition wall 350. The second electrode 270 may include a reflective metal, such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), or lithium (Li), or a transparent conductive oxide (TCO), such as an indium tin oxide (ITO) or an indium zinc oxide (IZO).

The first electrode 191, the emission layer 370, and the second electrode 270 may configure a light-emitting device LED, and here, the first electrode 191 may be an anode that is the hole injection electrode, and the second electrode 270 may be a cathode that is the electron injection electrode. However, without being limited to this, the anode and the cathode may be provided in an opposite way depending on corresponding methods for driving the display device.

Light is emitted when the holes and the electrons are injected into the emission layer 370 from the first electrode 191 and the second electrode 270, and excitons, which are a combination of the injected holes and electrons, fall to the ground state from the excited state.

In one or more embodiments, an encapsulation layer may be further positioned on the second electrode 270. The encapsulation layer protects the light emitting diode LED from moisture or oxygen that may infiltrate from outside, and may include at least one inorganic layer and at least one organic layer. For example, the encapsulation layer may have a shape in which a first inorganic encapsulation layer, an organic encapsulation layer, and a second inorganic encapsulation layer are stacked. This, however, is an example, and numbers of the inorganic layers and the organic layers configuring the encapsulation layer may be variable in many ways.

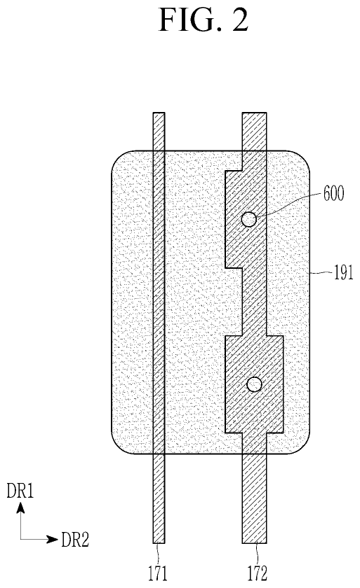

Shapes of a second data conductor of the display device and a first electrode in a plan view according to one or more embodiments will now be described with reference to FIG. 2.

FIG. 2 shows a top plan view of some layers of a display device according to one or more embodiments. FIG. 2 shows a data line, a driving voltage line, and a first electrode of the display device according to one or more embodiments.

As shown in FIG. 1 and FIG. 2, the first electrode 191 of the display device according to one or more embodiments may overlap the data line 171 and the driving voltage line 172.

The first electrode 191 may have a substantially polygonal shape in a plan view, and a corner portion may have a curved chamfered shape. For example, the first electrode 191 may be configured as a rectangle including two sides extending in a first direction DR1, and two sides extending in a second direction DR2 that is perpendicular to the first direction DR1. The two sides extending in the first direction DR1 may be long sides, and the two sides extending in the second direction DR2 may be short sides. However, without being limited to this, the first electrode 191 may form a square, a rhombus, a circle, or a hexagon in a plan view.

The data line 171 and the driving voltage line 172 may extend in parallel to each other. For example, the data line 171 and the driving voltage line 172 may extend in the first direction DR1. That is, the data line 171 and the driving voltage line 172 may extend in parallel to one side of the first electrode 191. However, this is not limited thereto, and the data line 171 and the driving voltage line 172 may extend in an oblique way with respect to one side of the first electrode 191.

The data line 171 may overlap at least part of the first electrode 191. For example, the data line 171 may overlap a left portion of the first electrode 191. That is, the data line 171 may overlap a region between a center portion of the first electrode 191 and a left edge. However, the position on which the data line 171 overlaps the first electrode 191 is not limited thereto, and it is variable in many ways. The data line 171 may have a width of about 1 μm to 7 μm, which is an example, and a range of the width of the data line 171 is not limited thereto. The data line 171 is shown to have a constant width, but it may have other widths. A region (e.g., predetermined region) of the data line 171 may have a relatively greater width.

The driving voltage line 172 may overlap at least part of the first electrode 191. For example, the driving voltage line 172 may overlap a right portion of the first electrode 191. That is, the driving voltage line 172 may overlap a region between the center portion of the first electrode 191 and a right edge. However, the position on which the driving voltage line 172 overlaps the first electrode 191 is not limited thereto, and it is variable in many ways. For example, the driving voltage line 172 may overlap the left portion of the first electrode 191, and the data line 171 may overlap the right portion of the first electrode 191. The driving voltage line 172 may have the width of about 4 μm to about 12 μm, which is an example, and a range of the width of the driving voltage line 172 is not limited thereto. The driving voltage line 172 may have various widths depending on the position. A region (e.g., predetermined region) of the driving voltage line 172 may have a relatively greater width.

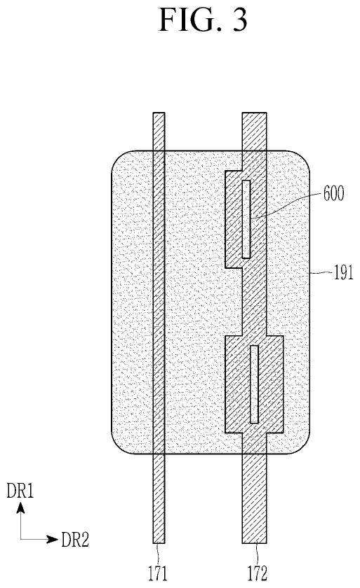

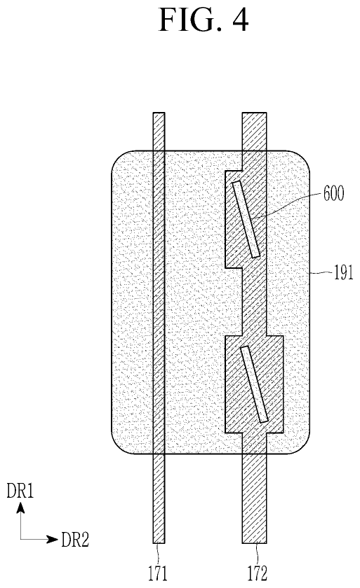

The driving voltage line 172 may include, or define, an opening pattern 600. The opening pattern 600 may be formed on a portion on which the width of the driving voltage line 172 is relatively great. When the opening pattern 600 is formed on a portion on which the width of the driving voltage line 172 is relatively small, the driving voltage line 172 may be disconnected. As the opening pattern 600 is formed on a portion on which the width of the driving voltage line 172 is relatively great, the likelihood of a disconnection defect of the driving voltage line 172 may be reduced or prevented. The opening pattern 600 may have a circular shape in a plan view. However, the shape of the opening pattern 600 is not limited thereto, and various shapes of the opening pattern 600 will now be described with reference to FIG. 3 and FIG. 4.

FIG. 3 and FIG. 4 show top plan views of some layers of a display device according to one or more embodiments. FIG. 3 and FIG. 4 show a data line, a driving voltage line, and a first electrode of the display device.

As shown in FIG. 3, the opening pattern 600 of the driving voltage line 172 may have a bar shape. The opening pattern 600 may have a bar shape substantially extending in the first direction DR1. That is, the direction in which the opening pattern 600 extends may substantially correspond to the direction in which the driving voltage line 172 extends.

As shown in FIG. 4, the opening pattern 600 of the driving voltage line 172 may have a bar shape extending in an oblique direction with respect to the first direction DR1. An inclined angle of the opening pattern 600 with respect to the first direction DR1 may be changed in many ways. The opening pattern 600 is shown to be inclined counterclockwise with respect to the first direction DR1, but without being limited thereto, the opening pattern 600 may be inclined clockwise with respect to the first direction DR1.

The shape of the opening pattern 600 in a plan view is variable in many ways in addition to the shapes shown in FIG. 2 to FIG. 4. For example, the opening pattern 600 may have an oval shape, a dot pattern, a polygonal shape, a zigzag pattern, and a wave pattern.

The number of the opening patterns 600 overlapping the first electrode 191 is shown as 2 but is not limited thereto. The number of the opening pattern 600 overlapping the first electrode 191 may be 1, may be 3 or more, and may be changed in various ways.

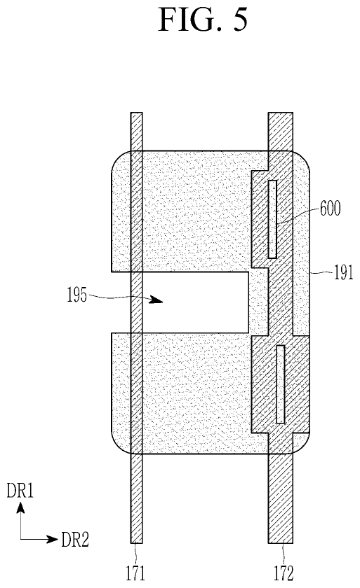

Regarding the display device according to one or more embodiments, the shape of the first electrode in a plan view and the position on which the second data conductor overlaps the first electrode are variable in many ways. Referring to FIG. 5 to FIG. 8, numerous exemplary variations of the second data conductor and the first electrode of one or more embodiments of the display device will be described.

FIG. 5 to FIG. 8 show top plan views of some layers of a display device according to one or more embodiments. FIG. 5 to FIG. 8 show a data line, a driving voltage line, and a first electrode of the display device according to one or more embodiments.

As shown in FIG. 5, the first electrode 191 may include, or define, an opening pattern 195. The entire shape, or overall shape, of the first electrode 191 in a plan view may be, substantially, a rectangular shape similar to previously described embodiments, and an opening pattern 195 from which a region (e.g., predetermined region) of the first electrode 191 is removed may be formed. The opening pattern 195 may substantially have a rectangular shape in a plan view. For example, the opening pattern 195 of the first electrode 191 may have a rectangular shape including two sides extending in the first direction DR1, and two sides extending in the second direction DR2 that is perpendicular to the first direction DR1. In this instance, the two sides extending in the first direction DR1 may be short sides, and the two sides extending in the second direction DR2 may be long sides. The opening pattern 195 may be positioned on the center portion and the left portion of the first electrode 191. The shape and the position of the opening pattern 195 are not limited thereto, and may be variable in many ways.

The data line 171 may overlap at least part of the first electrode 191. For example, the data line 171 may overlap the left portion of the first electrode 191. The data line 171 may be positioned near a left edge of the first electrode 191. According to one or more embodiments, the data line 171 may overlap the left edge of the first electrode 191. One side of the data line 171 may correspond to the left edge of the first electrode 191. The data line 171 may overlap the opening pattern 195 of the first electrode 191.

The driving voltage line 172 may overlap at least part of the first electrode 191. For example, the driving voltage line 172 may overlap the right portion of the first electrode 191. The driving voltage line 172 may be positioned near a right edge of the first electrode 191. According to one or more embodiments, the driving voltage line 172 may overlap the right edge of the first electrode 191. One side of the driving voltage line 172 may correspond to the right edge of the first electrode 191. The driving voltage line 172 may include, or define, an opening pattern 600, and the opening pattern 600 of the driving voltage line 172 may overlap the first electrode 191. The driving voltage line 172 might not overlap the opening pattern 195 of the first electrode 191. The opening pattern 600 of the driving voltage line 172 might not overlap the opening pattern 195 of the first electrode 191. However, without being limited thereto, the driving voltage line 172 may overlap the opening pattern 195 of the first electrode 191, and the opening pattern 600 of the driving voltage line 172 may overlap the opening pattern 195 of the first electrode 191.

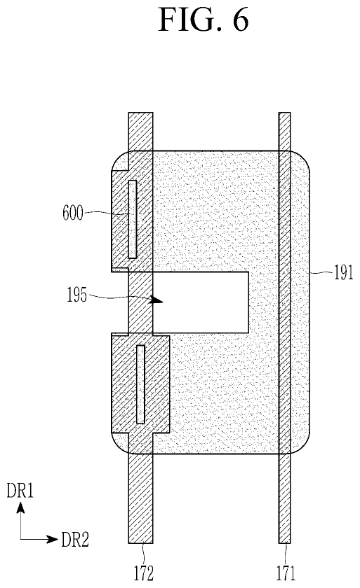

As shown in FIG. 6, the first electrode 191 may include, or define, an opening pattern 195, and the data line 171 and the driving voltage line 172 may overlap the first electrode 191.

The data line 171 may overlap the right portion of the first electrode 191. The data line 171 may be positioned near the right edge of the first electrode 191. According to one or more embodiments, the data line 171 may overlap the right edge of the first electrode 191. One side of the data line 171 may correspond to the right edge of the first electrode 191. The data line 171 might not overlap the opening pattern 195 of the first electrode 191.

The driving voltage line 172 may overlap the left portion of the first electrode 191. The driving voltage line 172 may be positioned near the left edge of the first electrode 191. According to one or more embodiments, the driving voltage line 172 may overlap the left edge of the first electrode 191. One side of the driving voltage line 172 may correspond to the left edge of the first electrode 191. The driving voltage line 172 may include, or define, an opening pattern 600, and the opening pattern 600 of the driving voltage line 172 may overlap the first electrode 191. The driving voltage line 172 may overlap the opening pattern 195 of the first electrode 191. The opening pattern 600 of the driving voltage line 172 might not overlap the opening pattern 195 of the first electrode 191. However, without being limited thereto, the opening pattern 600 of the driving voltage line 172 may overlap the opening pattern 195 of the first electrode 191.

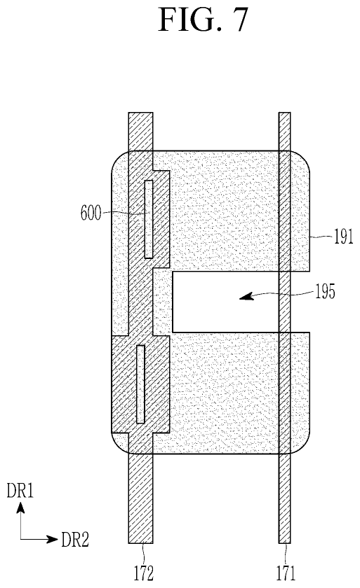

As shown in FIG. 7, the first electrode 191 may include, or define, the opening pattern 195, and the data line 171 and the driving voltage line 172 may overlap the first electrode 191.

The entire shape of the first electrode 191 in a plan view may be, substantially, a rectangular shape, and the shape of the opening pattern 195 of the first electrode 191 in a plan view may be, substantially, a rectangular shape. The opening pattern 195 may be positioned on the center portion and the right portion of the first electrode 191. The shape and the position of the opening pattern 195 are not limited thereto, and may be variable in many ways.

The data line 171 may overlap the right portion of the first electrode 191. The data line 171 may be positioned near the right edge of the first electrode 191. According to one or more embodiments, the data line 171 may overlap the right edge of the first electrode 191. One side of the data line 171 may correspond to the right edge of the first electrode 191. The data line 171 may overlap the opening pattern 195 of the first electrode 191.

The driving voltage line 172 may overlap the left portion of the first electrode 191. The driving voltage line 172 may be positioned near the left edge of the first electrode 191. According to one or more embodiments, the driving voltage line 172 may overlap the left edge of the first electrode 191. One side of the driving voltage line 172 may correspond to the left edge of the first electrode 191. The driving voltage line 172 may include, or define, an opening pattern 600, and the opening pattern 600 may overlap the first electrode 191. The driving voltage line 172 might not overlap the opening pattern 195 of the first electrode 191. The opening pattern 600 might not overlap the opening pattern 195. However, without being limited thereto, the driving voltage line 172 may overlap the opening pattern 195, and the opening pattern 600 may overlap the opening pattern 195.

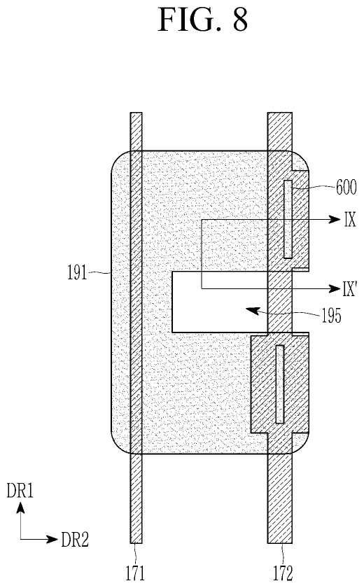

As shown in FIG. 8, the first electrode 191 may include, or define, an opening pattern 195, and the data line 171 and the driving voltage line 172 may overlap the first electrode 191.

The data line 171 may overlap the left portion of the first electrode 191. The data line 171 may be positioned near the left edge of the first electrode 191. According to one or more embodiments, the data line 171 may overlap the left edge of the first electrode 191. One side of the data line 171 may correspond to the left edge of the first electrode 191. The data line 171 might not overlap the opening pattern 195 of the first electrode 191.

The driving voltage line 172 may overlap the right portion of the first electrode 191. The driving voltage line 172 may be positioned near the right edge of the first electrode 191. According to one or more embodiments, the driving voltage line 172 may overlap the right edge of the first electrode 191. One side of the driving voltage line 172 may correspond to the right edge of the first electrode 191. The driving voltage line 172 may include, or define, the opening pattern 600, and the opening pattern 600 may overlap the first electrode 191. The driving voltage line 172 may overlap the opening pattern 195 of the first electrode 191. The opening pattern 600 of the driving voltage line 172 might not overlap the opening pattern 195 of the first electrode 191. However, without being limited thereto, the opening pattern 600 may overlap the opening pattern 195.

As described above, the second data conductor including a data line and a driving voltage line may overlap the first electrode. The second data conductor may include, or define, an opening pattern, and the first electrode may include, or define, an opening pattern. In this instance, a ratio of a combined area of the opening pattern of the second data conductor and the opening pattern of the first electrode to a combined area of the second data conductor and the first electrode may be equal to or greater than about 27.2%. The above ratio, which may be referred to as the ratio of the opening pattern, is variable in many ways, and when the ratio of the opening pattern is equal to or greater than about 27.2%, the gas remaining in the insulating layer may be efficiently discharged. The higher the ratio of the opening pattern becomes, the more advantageous the effect of discharging the gas may be, and the more disadvantageous the resistance of the wire may be. Hence, the ratio of the opening pattern may be appropriately selected by considering, or balancing, the effect of discharging the gas and the resistance.

The case in which the first electrode includes, or defines, an opening pattern as shown in FIG. 5 to FIG. 8 may be relatively more advantageous than the case in which the first electrode includes no opening pattern as shown in FIG. 3 and FIG. 4, with respect to a viewpoint of the effect of discharging the gas. In addition, the case in which the wire with a relatively great width is designed to overlap the opening pattern of the first electrode as shown in FIG. 6 and FIG. 8 may be relatively more advantageous than the case in which the wire with a relatively great width does not overlap the opening pattern of the first electrode as shown in FIG. 5 and FIG. 7, with respect to a viewpoint of the effect of discharging the gas.

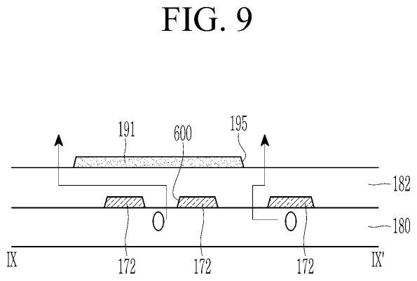

A respective display devices according to one or more embodiments will now be compared and described with reference to FIG. 9 to FIG. 11 together with FIG. 8.

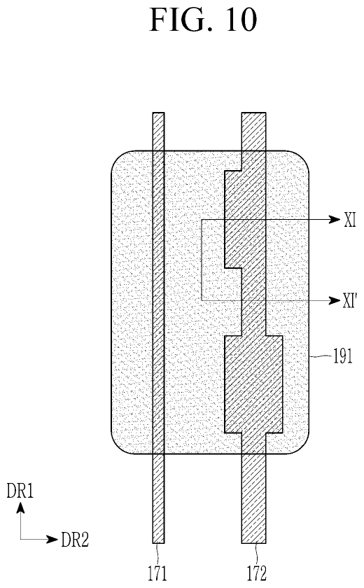

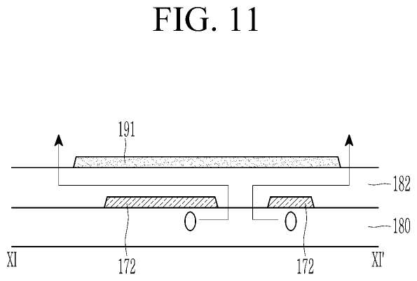

FIG. 9 shows a cross-sectional view taken along the line IX-IX′ of FIG. 8, FIG. 10 shows a top plan view of some layers of a display device according to one or more embodiments, and FIG. 11 shows a cross-sectional view taken along the line XI-XI′ of FIG. 10.

As shown in FIG. 8 and FIG. 9, regarding the display device according to one or more embodiments, a first passivation layer 180 may be positioned below the second data conductor including a data line 171 and a driving voltage line 172, and a second passivation layer 182 may be positioned between the second data conductor and the first electrode 191. The first passivation layer 180 and the second passivation layer 182 may include an organic insulating material, and gas may be generated in the first passivation layer 180 and the second passivation layer 182 in the manufacturing process. The generated gas may be moved to upper sides of the first passivation layer 180 and the second passivation layer 182 to be discharged. However, a portion of the gas may be shielded by the second data conductor and the first electrode 191 to not be discharged, and therefore may remain in the first passivation layer 180 and the second passivation layer 182.

Regarding the display device according to one or more embodiments, the opening pattern 600 may be formed in the second data conductor, and the opening pattern 195 may be formed in the first electrode 191. According to one or more embodiments, the opening pattern 195 of the first electrode 191 may be omitted. By the opening pattern 600 of the second data conductor, a moving path of the gas generated in the first passivation layer 180 may be reduced so that the gas may be fluently discharged. By the opening pattern 195 of the first electrode 191, a moving path of the gas generated in the first passivation layer 180 and the second passivation layer 182 may be reduced so that the gas may be fluently discharged.

The opening pattern 600 is shown to be formed in the driving voltage line 172 from among the second data conductor, but is not limited thereto. The second data conductor may include various types of wires in addition to the driving voltage line 172, and the opening pattern may be formed in other wires. For example, the data line 171, the initialization voltage line, and the common voltage line may include, or define, the opening pattern.

As shown in FIG. 10 and FIG. 11, regarding the display device according to one or more embodiments, a first passivation layer 180 is positioned below the second data conductor including a data line 171 and a driving voltage line 172, and a second passivation layer 182 may be positioned between the second data conductor and the first electrode 191.

Regarding the display device according to one or more embodiments, the opening pattern is not formed in the second data conductor, and the opening pattern is not formed in the first electrode 191. The driving voltage line 172 from among the second data conductor may have a relatively great width. Hence, the gas generated in the first passivation layer 180 may be shielded by the driving voltage line 172, and may not be discharged to the outside. By the driving voltage line 172 having a great width, the moving path of the gas increases, and the first electrode 191 overlapping the driving voltage line 172 has a greater width, so the moving path of the gas further increases. The moving path of the gas may be increased by other wires included in the second data conductor in addition to the driving voltage line 172. Hence, the gas generated in the first passivation layer 180 and the second passivation layer 182 may be shielded by the second data conductor and the first electrode 191, and may remain in the first passivation layer 180 and the second passivation layer 182 to influence other components.

Regarding the display device according to one or more embodiments, as described above, by reducing the moving path of the gas by the opening pattern 600 of the second data conductor and the opening pattern 195 of the first electrode 191, thereby allowing the gas to be fluently discharged, a remaining amount of the gas in the first passivation layer 180 and the second passivation layer 182 may be reduced, and influences to other components may be reduced or prevented.

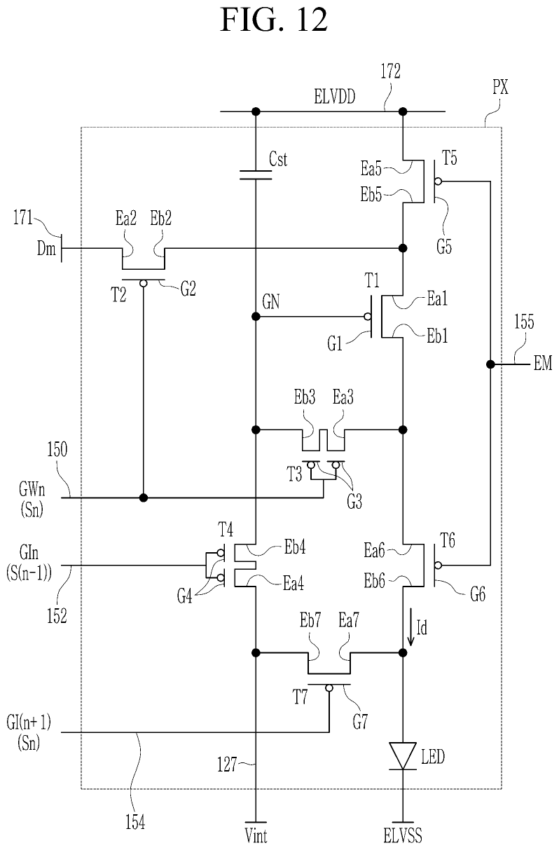

One transistor included in the respective pixels has been described with reference to FIG. 1, and as described above, the pixels may respectively include a plurality of transistors. A pixel of a display device according to one or more embodiments will now be described with reference to FIG. 12.

FIG. 12 shows a circuit diagram of a pixel of a display device according to one or more embodiments.

As shown in FIG. 12, the display device includes a plurality of pixels PX for displaying images, and a plurality of signal lines 127, 150, 152, 154, 171, and 172. One pixel PX may include a plurality of transistors T1, T2, T3, T4, T5, T6, and T7 connected to the signal lines 127, 150, 152, 154, 171, and 172, a capacitor Cst, and at least one light emitting diode LED. The present embodiments will depict one pixel PX including one light emitting diode LED.

The signal lines 127, 150, 152, 154, 155, 171, and 172 may include an initialization voltage line 127, a plurality of scan lines 150, 152, and 154, a light emitting control line 155, a data line 171, and a driving voltage line 172. At least some of the signal lines 127, 150, 152, 154, 155, 171, and 172 may be made of the second data conductor as described above. For example, the initialization voltage line 127, the data line 171, and the driving voltage line 172 may be made of the second data conductor. The initialization voltage line 127 may transmit an initialization voltage Vint. The scan lines 150, 152, and 154 may respectively transmit scan signals GWn, Gln, and Gl(n+1). The scan signals GWn, Gln, and Gl(n+1) may transmit a gate-on voltage and a gate-off voltage for turning on/off the transistors T2, T3, T4, and T7 included by the pixel PX.

The scan lines 150, 152, and 154 connected to the pixel PX may include a first scan line 150 for transmitting the scan signal GWn, a second scan line 152 for transmitting the scan signal Gln with a gate-on voltage at another timing that is different from that of the first scan line 150, and a third scan line 154 for transmitting the scan signal Gl(n+1). In the present embodiments, an example for the second scan line 152 to transmit a gate-on voltage at a timing that is prior to that of the first scan line 150 will be generally described. For example, when the scan signal GWn is an n-th scan signal Sn (n is a natural number that is equal to or greater than 1) from among the scan signals applied for one frame, the scan signal Gln may be a previous-stage scan signal, such as a (n−1)-th scan signal S(n−1), and the scan signal Gl(n+1) may be the n-th scan signal Sn. However, the present disclosure is not limited thereto, and the scan signal Gl(n+1) may be different from the n-th scan signal Sn.

The light emitting control line 155 may transmit a control signal, and may transmit a light emitting control signal EM for controlling light emission of the light emitting diode LED included by the pixel PX. The light emitting control line 155 may transmit the control signals, such as the gate-on voltage and the gate-off voltage, and the control signals may have waveforms that are different from those of the scan signals transmitted by the scan lines 150, 152, and 154.

The data line 171 may transmit a data signal Dm, and the driving voltage line 172 may transmit a driving voltage ELVDD. The data signal Dm may have different voltage levels according to image signals input to the display device, and the driving voltage ELVDD may substantially have a constant level.

In one or more embodiments, the display device may further include a driver for transmitting signals to the signal lines 127, 150, 152, 154, 171, and 172.

The transistors T1, T2, T3, T4, T5, T6, and T7 included by one pixel PX may include a first transistor T1, a second transistor T2, a third transistor T3, a fourth transistor T4, a fifth transistor T5, a sixth transistor T6, and a seventh transistor T7.

The first scan line 150 may transmit the scan signal GWn to the second transistor T2 and the third transistor T3, the second scan line 152 may transmit the scan signal Gln to the fourth transistor T4, the third scan line 154 may transmit the scan signal Gl(n+1) to the seventh transistor T7, and the light emitting control line 155 may transmit the light emitting control signal EM to the fifth transistor T5 and the sixth transistor T6.

A gate electrode G1 of the first transistor T1 is connected to a first end of the capacitor Cst through a driving gate node GN. A first electrode Ea1 of the first transistor T1 is connected to the driving voltage line 172 through the fifth transistor T5. A second electrode Eb1 of the first transistor T1 is connected to an anode of the light emitting diode LED through the sixth transistor T6. The first transistor T1 may receive the data signal Dm through the data line 171, and may supply a driving current Id to the light emitting diode LED according to a switching operation by the second transistor T2.

A gate electrode G2 of the second transistor T2 is connected to the first scan line 150, a first electrode Ea2 of the second transistor T2 is connected to the data line 171, and a second electrode Eb2 of the second transistor T2 is connected to the first electrode Ea1 of the first transistor T1, and is connected to the driving voltage line 172 through the fifth transistor T5. The second transistor T2 may be turned on by the scan signal GWn received through the first scan line 150 and may transmit the data signal Dm received from the data line 171 to the first electrode Ea1 of the first transistor T1.

A gate electrode G3 of the third transistor T3 is connected to the first scan line 150. A first electrode Ea3 of the third transistor T3 is connected to the second electrode Eb1 of the first transistor T1, and is connected to the anode of the light emitting diode LED through the sixth transistor T6. A second electrode Eb3 of the third transistor T3 is connected to a second electrode Eb4 of the fourth transistor T4, to a first end of the capacitor Cst, and to the gate electrode G1 of the first transistor T1. The third transistor T3 may be turned on by the scan signal GWn received through the first scan line 150, and may connect the gate electrode G1 and the second electrode Eb1 of the first transistor T1 to thus diode-connect the first transistor T1.

A gate electrode G4 of the fourth transistor T4 is connected to the second scan line 152, a first electrode Ea4 of the fourth transistor T4 is connected to an initialization voltage Vint terminal, and a second electrode Eb4 of the fourth transistor T4 is connected to the second electrode Eb3 of the third transistor T3, to the first end of the capacitor Cst, and to the gate electrode G1 of the first transistor T1. The fourth transistor T4 may be turned on by the scan signal Gln received through the second scan line 152 to transmit the initialization voltage Vint to the gate electrode G1 of the first transistor T1, and may perform an initialization operation for initializing a voltage at the gate electrode G1 of the first transistor T1.

A gate electrode G5 of the fifth transistor T5 is connected to the light emitting control line 155, a first electrode Ea5 of the fifth transistor T5 is connected to the driving voltage line 172, and a second electrode Eb5 of the fifth transistor T5 is connected to the first electrode Ea1 of the first transistor T1 and the second electrode Eb2 of the second transistor T2.

A gate electrode G6 of the sixth transistor T6 is connected to the light emitting control line 155, a first electrode Ea6 of the sixth transistor T6 is connected to the second electrode Eb1 of the first transistor T1 and to the first electrode Ea3 of the third transistor T3, and a second electrode Eb6 of the sixth transistor T6 is electrically connected to the anode of the light emitting diode LED. The fifth transistor T5 and the sixth transistor T6 may be concurrently or substantially simultaneously turned on by the light emitting control signal EM received through the light emitting control line 155, and the driving voltage ELVDD may be compensated through the diode-connected first transistor T1 and may be transmitted to the light emitting diode LED.

A gate electrode G7 of the seventh transistor T7 is connected to the third scan line 154, a first electrode Ea7 of the seventh transistor T7 is connected to the second electrode Eb6 of the sixth transistor T6 and to the anode of the light emitting diode LED, and a second electrode Eb7 of the seventh transistor T7 is connected to the initialization voltage Vint terminal and the first electrode Ea4 of the fourth transistor T4.

The transistors T1, T2, T3, T4, T5, T6, and T7 may each be a p-type channel transistors, such as a PMOS, and without being limited thereto, at least one of the transistors T1, T2, T3, T4, T5, T6, and T7 may be a n-type channel transistor.

The first end of the capacitor Cst is connected to the gate electrode G1 of the first transistor T1, and the second end is connected to the driving voltage line 172. The cathode of the light emitting diode LED may be connected to a common voltage ELVSS terminal for receiving and transmitting a common voltage ELVSS.

The one pixel PX has been described in the above to include the seven transistors T1 to T7, the one storage capacitor Cst, and the one light emitting diode LED, this, however, is an example, and the number of the transistors, the number of the capacitors, the number of the light emitting diodes LED, and connection relationships thereof are modifiable in various ways.

While this disclosure has been described in connection with what is presently considered to be practical embodiments, it is to be understood that the present disclosure is not limited to the disclosed embodiments, but, on the contrary, is intended to cover various modifications and equivalent arrangements included within the spirit and scope of the appended claims, with functional equivalents thereof to be included therein.

Description of Some Reference Characters

| | |
|---|---|
| 110: substrate | 191: first electrode |
| 195: opening pattern of first electrode | 171: data line |
| 172: driving voltage line | 180: first passivation layer |
| 182: second passivation layer | 510: connection electrode |
| 600: opening pattern of driving voltage line | |

What is claimed is:

1. A display device comprising:
a substrate;
a transistor on the substrate;
a first electrode connected to the transistor;
a first passivation layer between the transistor and the first electrode;
a wire on the first passivation layer, overlapping the first electrode, and defining an opening pattern; and
a second passivation layer between the wire and the first electrode.

2. The display device of claim 1, wherein the first passivation layer comprises an organic insulating material.

3. The display device of claim 2, wherein the second passivation layer comprises an organic insulating material.

4. The display device of claim 1, wherein the opening pattern of the wire overlaps the first electrode.

5. The display device of claim 1, wherein the opening pattern of the wire has at least one of a circular shape, a polygonal shape, and a bar shape.

6. The display device of claim 1, wherein the wire extends in a first direction, and
wherein the opening pattern of the wire has a bar shape extending in the first direction.

7. The display device of claim 1, wherein the wire extends in a first direction, and
wherein the opening pattern of the wire has a bar shape extending in an oblique direction with respect to the first direction.

8. The display device of claim 1, wherein the wire overlaps a region between a center portion of the first electrode and an edge on one side of the first electrode.

9. The display device of claim 1, wherein the wire is near an edge on one side of the first electrode.

10. The display device of claim 1, wherein the wire overlaps an edge on one side of the first electrode.

11. The display device of claim 10, wherein one side of the wire corresponds to an edge on one side of the first electrode.

12. The display device of claim 1, wherein the first electrode defines an opening pattern.

13. The display device of claim 12, wherein the first electrode has a rectangular shape comprising two long sides extending in a first direction, and two short sides extend in a second direction that is perpendicular to the first direction,
wherein the opening pattern of the first electrode has a rectangular shape comprising two short sides extending in the first direction, and two long sides extending in the second direction, and
wherein the wire extends in the first direction.

14. The display device of claim 13, wherein the opening pattern of the first electrode is at a center portion of the first electrode and an edge on one side of the first electrode.

15. The display device of claim 14, wherein the wire overlaps the opening pattern of the first electrode.

16. The display device of claim 12, wherein the opening pattern of the wire overlaps the first electrode and does not overlap the opening pattern of the first electrode.

17. The display device of claim 1, further comprising:
a connection electrode for connecting the transistor to the first electrode, and at a same layer as the wire.

18. The display device of claim 1, wherein a voltage is applied to the wire, which is connected to the transistor.

19. The display device of claim 18, wherein the wire comprises:
a data line for applying a data signal; and
a driving voltage line for applying a driving voltage, having a width that is greater than that of the data line, and having the opening pattern formed therein.

20. The display device of claim 19, wherein the wire further comprises:
an initialization voltage line for applying an initialization voltage; and
a common voltage line for applying a common voltage, and
wherein the opening pattern is formed in the initialization voltage line and the common voltage line.
